(19) United States
(12) Patent Application Publication
(10) Pub. No.: US 2004/0212849 A1
(43) Pub. Date: Oct. 28, 2004

(54) Image reading device, program and method

(75) Inventor: Takahiro Ikeda, Toshina-ku (JP)

Correspondence Address: OLIFF & BERRIDGE, PLC, P.O. BOX 19928, ALEXANDRIA, VA, 22320, US

(73) Assignee: NIKON CORPORATION, Tokyo (JP)

(21) Appl. No.: 10/821,993

(22) Filed: Apr. 12, 2004

(30) Foreign Application Priority Data
Apr. 14, 2003 (JP) 2003-109591

(51) Int. Cl. H04N 1/04; G03F 3/10

(52) U.S. Cl. 358/474; 358/527

(57) ABSTRACT

An image reading device includes a document reader that reads an image of a document, and a controller. The controller performs prescanning of the document with the document reader, and performs at least one of: (i) generating a preview image of the document, and (ii) determining a reading condition of the document. The controller receives a reading resolution to be used during main scanning. When the reading resolution for use during main scanning is higher than a reading resolution used for prescanning, the controller causes the main scanning of the document, and outputs a main scanning image of the document. When the reading resolution to be used during main scanning is not greater than the reading resolution used for prescanning, the controller, instead of causing main scanning, outputs an alternative image that is based on the read image obtained from the prescanning.

### INCORPORATION BY REFERENCE

The disclosure of the following priority application is herein incorporated by reference in its entirety: Japanese Patent Application No. 2003-109591 filed Apr. 14, 2003.

### BACKGROUND OF THE INVENTION

1. Field of Invention

This invention relates to an image reading device, method and program for reading an image from a document (e.g., a film, a sheet of paper, a three-dimensional object, or the like).

2. Description of Related Art

A conventional image reading device initially performs prescanning in order to determine a reading condition of the document and to obtain a preview image of the document. See, for example, Japanese Laid-Open Patent Application 10-232436. Subsequently, the image reading device performs main scanning of the document and outputs the read main-scanned image as a final result.

### SUMMARY OF THE INVENTION

In the case of the above-mentioned conventional image reading device, it is necessary to perform at least two scanning operations, namely prescanning and main scanning, in order to read one document, and this takes time.

Therefore, one object of this invention is to provide a device, method and program which simplifies an image reading operation.

An image reading device according to one aspect of the invention includes a document reader and a controller that controls prescanning, main scanning, image formation and that receives operator input. The document reader is capable of reading an image of a document. The controller performs prescanning of the document by controlling the document reader and by performing at least one of: (i) generating a preview image of the document, and (ii) determining a reading condition of the document. The controller receives a user input for a reading resolution to be applied during main scanning. The controller can cause the output of a main scanning image by controlling the document reader so as to perform main scanning of the document when the reading resolution to be used during the main scanning is higher than the reading resolution used for the prescanning. The controller can, as an alternative to performing main scanning, generate and output an alternative image based on the read image obtained from the prescanning, when the reading resolution selected for the main scanning is less than or equal to the reading resolution used for the prescanning. Preferably the alternative image is generated and output by: (i) converting the resolution of the read image obtained from the prescanning, (ii) generating the alternative image adjusted to the resolution selected for the main scanning, and (iii) outputting the alternative image instead of the main scanning image.

According to another aspect of the invention, the controller of the image reading device determines whether a difference between (1) a reading condition used during the prescanning and (2) a reading condition selected to be used during the main scanning, is outside of a predetermined allowable range. If the difference is outside of the predetermined allowable range, regardless of the reading resolution, the controller performs the main scanning and outputs the main scanned image.

The above-mentioned predetermined allowable range preferably is determined by assessing, for example, through an image quality visual impact test or the like, whether a user can accept image quality variations that occur due to differences in the reading conditions. For example, the allowable range is set to be narrow if the user reacts negatively to even a slight difference in a reading condition, and so main scanning should be implemented even if a slight difference exists. In this case, the probability of being able to omit the main scanning operation decreases, but an image read at suitable reading conditions is always output. Conversely, the allowable range is set to be wide if the user does not object to a difference in the reading condition, and the probability of being able to omit the main scanning operation increases.

When setting the predetermined allowable range, it is preferable to consider the presence and/or type of subsequent image corrections. For example, if a difference in the reading conditions is within a correctable range, it is preferable to judge the image quality change as being within the allowable range.

According to another aspect of the invention, the controller of the image reading device, when performing the alternative to main scanning, selects an image correction to perform for the alternative image according to the difference between (1) the reading condition used during the prescanning and (2) the reading condition selected to be used during the main scanning, and then generates the alternative image to which the image correction has been performed.

With this type of operation, it is preferable to experimentally determine in advance, in correlation with reading condition differences (or the reading conditions of both scans), types of image corrections or correction parameters (strong or weak, etc.). In this case, since an image correction can be selected which reduces the effects of differences in the reading conditions of both scans, an alternative image closer in quality to that of a main scanning image can be output.

Furthermore, when the reading conditions for prescanning are constant each time, the above-described “selection of an image correction according to the difference in reading conditions” naturally becomes the same as “selection of an image correction according to only the main scanning reading conditions.”

Another aspect of the invention relates to a computer-executable program which controls a document reader to function as described above.

Another aspect of the invention relates to an image reading method which controls a document reader to read an image of a document. The method includes the steps of: performing prescanning of the document by controlling a document reader and performing at least one of: (i) generating a preview image of the document, and (ii) determining a reading condition of the document; and receiving a user input for a reading resolution to be applied during main scanning. The method further includes the step of either: (A) performing main scanning of the document by controlling the document reader and outputting the main scanning image when the reading resolution selected for use during the main scanning is higher than the reading resolution used for the prescanning; or (B) outputting an alternative image, instead of the main scanning image, when the reading resolution selected for the main scanning is less than or equal to the reading resolution used for the prescanning, the alternative image being based on the read image obtained from the prescanning. Preferably the alternative image is generated and output by: (i) converting the resolution of the read image obtained from the prescanning to the resolution selected for the main scanning; (ii) generating the alternative image adjusted to the resolution selected for the main scanning, and (iii) outputting the alternative image instead of the main scanning image.

### BRIEF DESCRIPTION OF THE DRAWINGS

The invention will be described in conjunction with the following drawings in which like reference numerals designate like elements and wherein:

FIG. 1 is a block diagram showing a structure of one exemplary embodiment of the invention;

FIGS. 2A-2B show a flowchart demonstrating an operation of the FIG. 1 embodiment; and

FIG. 3 is a diagram showing a dialog box of the FIG. 1 embodiment.

### DETAILED DESCRIPTION OF PREFERRED EXEMPLARY EMBODIMENTS

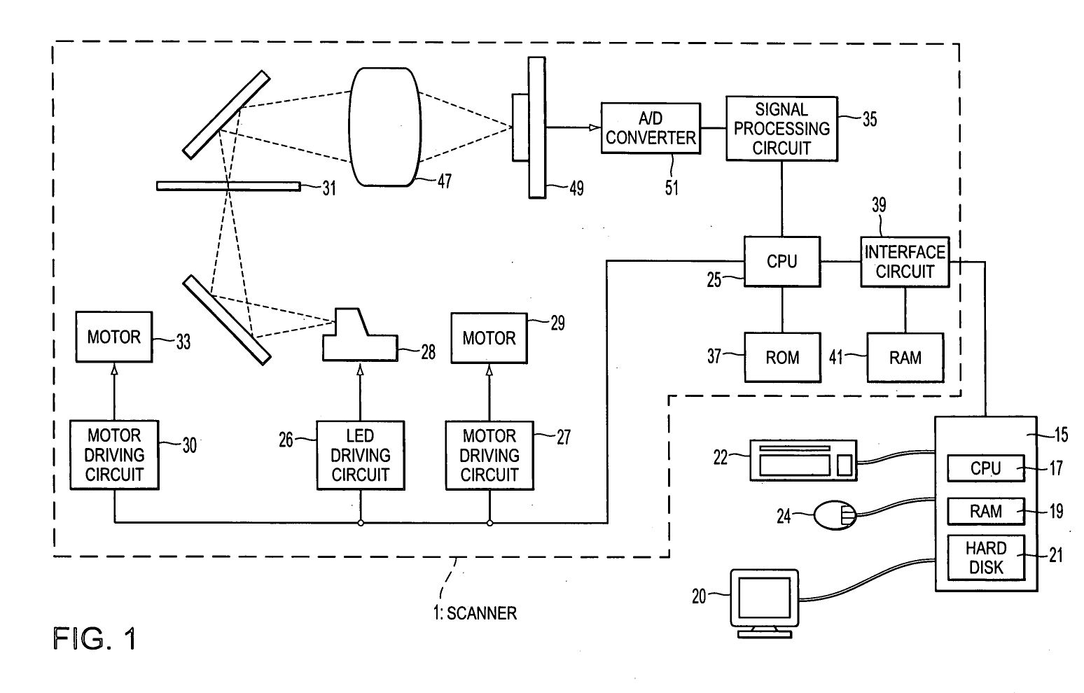

FIG. 1 is a block diagram showing a structure of one exemplary embodiment of the invention.

As shown in FIG. 1, a scanner 1 is used with a computer 15. The computer 15 is provided with a CPU 17, a RAM 19, and a hard drive 21. Furthermore, the computer 15 is connected to a monitor 20, a keyboard 22, and a mouse 24.

A CPU 25 also is provided in the scanner 1. An LED driving circuit 26 is connected to the CPU 25. The LED driving circuit 26 drives an illumination device 28 which illuminates a document 31. Additionally, a motor driving circuit 27 is connected to the CPU 25. This motor driving circuit 27 drives a motor 29 which scans the illumination device 28 so as to scan the illumination light across the document 31. Furthermore, a motor driving circuit 30 is connected to the CPU 25. This motor driving circuit 30 drives a motor 33 which moves the document 31. The CPU 25 is connected to a ROM 37 and an I/F (Interface) circuit 39. The I/F circuit 39 is connected to a RAM 41. Furthermore, the I/F circuit 39 is connected to the computer 15 via an undepicted I/F connector.

Furthermore, a lens 47 which images the light transmitted through the document 31, and a line sensor 49 which photoelectrically converts the optical image of the document 31 formed by the lens 47, are arranged in the scanner 1. The output of the line sensor 49 is digitally converted via an A/D converter 51, and then is provided to a signal processing circuit 35.

The illumination device 28, the lens 47, the line sensor 49, the motor 33, the motor 29, and the CPU 25 function as one example of a document reader according to an aspect of the invention.

The computer 15 is a controller that functions as one example of a prescanning section which controls a prescanning operation of the scanner 1.

The computer 15 is a controller that also functions as one example of a operation input section which receives a user input (for example, via the mouse 24 or keyboard 22).

The computer 15 is a controller that also functions as one example of a main scanning section that controls a main scanning operation of the scanner 1. The computer 15 is a controller that also functions as one example of an alternative image forming section that acts as an alternative to the main scanning section, so as to generate an alternative image from the read image obtained during prescanning, instead of generating an image from main scanning of the document.

The computer 15 executes a driver program as an image reading program according to an aspect of the invention.

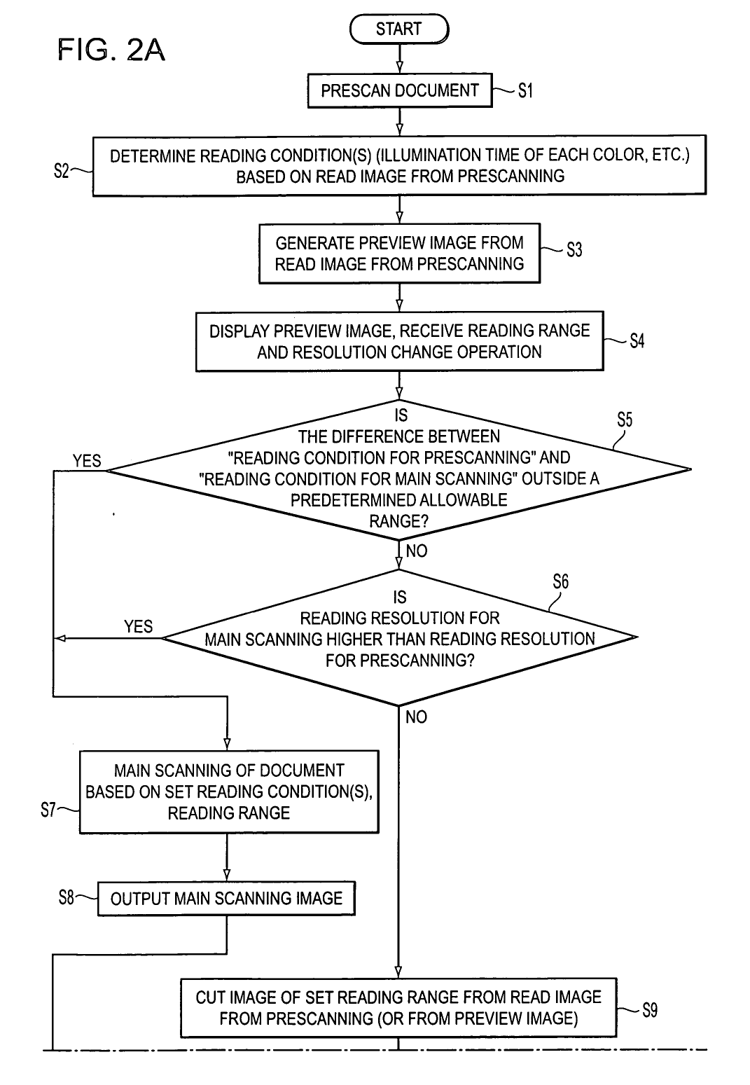

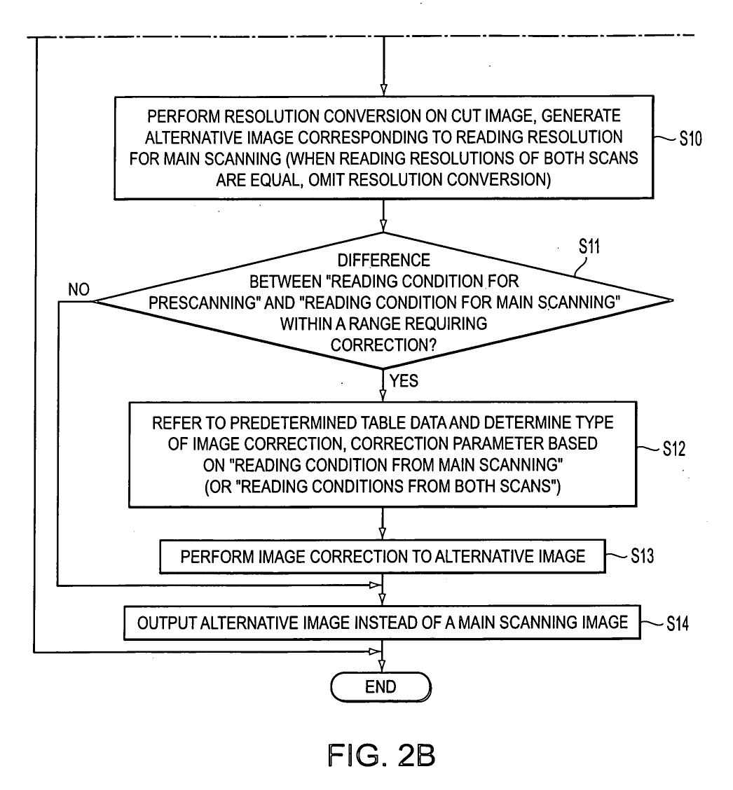

FIGS. 2A and 2B show a flowchart demonstrating an operation of the exemplary embodiment.

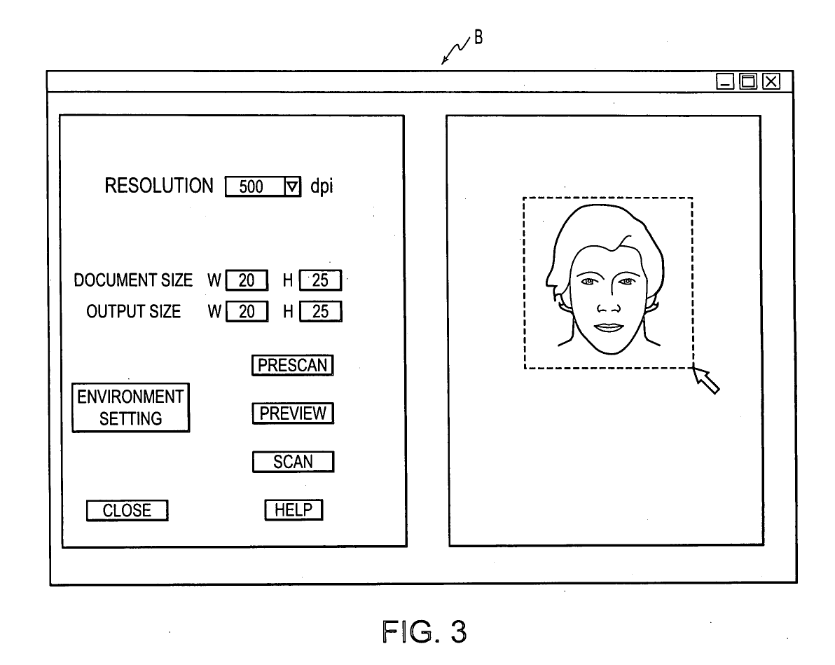

In step S1, the computer 15 displays a dialog box B shown in FIG. 3 by the execution of the driver program. A user instructs the computer 15 to execute a prescanning operation by actuating a prescanning button (icon) of the dialog box B.

The computer 15 transmits this instruction for the prescanning operation to the scanner 1. The CPU 25 of the scanner 1 performs prescanning of the document in accordance with a predetermined reading condition and resolution. In the present example, the predetermined reading resolution during prescanning is 500 dpi (dpi: number of dots per inch).

In step S2, the CPU 25 determines an appropriate reading condition(s) to be used during main scanning of the document, based on the read image obtained from prescanning. For example, the CPU 25 obtains a histogram distribution for the respective illumination colors with respect to the read image from prescanning. Based on the histogram distribution, the CPU 25 determines the illumination time and γ characteristic for each color during main scanning so as to ensure that conditions such as white balance are within an appropriate range without having the maximum light receiving amount of the light sensor 49 reach saturation. Various well known processes can be used in step S2 to determine the main scanning reading condition(s).

In step S3, the CPU 25 generates a preview image by performing white balance, γ correction, or the like with respect to the read image from prescanning.

In step S4, the preview image is transmitted to the computer 15 and displayed on a child window of the dialog box B. The user can input a desired reading range (shown by dotted lines in FIG. 3) on the child window of this preview image. Furthermore, the user can select the reading resolution to be used for main scanning by operating a list box or the like within the dialog box B.

After this type of input operation is completed, the user actuates a scan button (icon) of the dialog box B to instruct the computer 15 to perform a main scanning operation.

In step S5, the computer 15 determines whether the difference between “the reading condition used during prescanning” and “a reading condition which is selected for main scanning” is outside of a predetermined allowable range.

For example, in a state in which an image document is relatively dark (e.g., a positive film is insufficiently exposed), and there is a concern that the S/N (signal-to-noise ratio) will be insufficient with the illumination time used during prescanning, the computer 15 determines the state to be outside of the allowable range based on the difference between both reading conditions.

Additionally, for example, when there is a significant color imbalance in the original image, and the white balance is not well adjusted at each color illumination time used during prescanning, the computer 15 determines the state to be outside of the allowable range based on the difference between both reading conditions (i.e., the reading condition(s) used for prescanning and those selected for use with main scanning).

Here, if the difference is determined to be outside of the allowable range, the computer 15 proceeds to step S7. Meanwhile, if the difference is determined to be within the allowable range, the computer 15 proceeds to step S6.

In step S6, the computer 15 determines whether “the reading resolution which is selected for main scanning” is higher than “the reading resolution used during prescanning”.

Here, if the reading resolution is higher in main scanning, the computer 15 proceeds to step S7. Otherwise, the computer 15 proceeds to step S9.

In step S7, the computer 15 instructs the scanner 1 to perform main scanning of the document. The CPU 25 of the scanner 1 performs main scanning of the document in accordance with the reading conditions determined at step S2, and the reading range and resolution determined at step S4.

In step S8, the main scanned image generated by main scanning is output to the computer 15 side via the I/F circuit 39. After this operation, the document reading operation is completed.

In step S9, the computer 15 cuts the image from the read image read by prescanning (or the preview image generated from the read image) to the reading range set at step S4.

In step S10, the computer 15 performs resolution conversion for the cut image (if the resolution selected for main scanning is different from the resolution used for prescanning) and generates an alternative image corresponding to the reading resolution selected for main scanning. Furthermore, if the reading resolution of prescanning is the same as that of main scanning, the resolution conversion is omitted.

In step S11, the computer 15 determines whether image correction is desirable for the alternative image based on the difference between “the reading condition(s) used during prescanning” and “the reading condition(s) to be used for main scanning”.

Here, if image correction is needed, the computer 15 proceeds to step S12. Meanwhile, if image correction is not needed, the computer 15 proceeds to step S14.

In step S12, in a driver program of the computer 15, table data is prestored for determining types of image corrections and correction parameters. This table data can be created in advance by, for example, the following procedures.

(1) Various test documents are read under the reading condition during prescanning.

(2) For each of the test documents, the reading condition during main scanning is determined from the read image from prescanning.

(3) Each test document is read under the reading condition during main scanning.

(4) Image correction is experimentally performed for each test document with respect to the read image from prescanning. Based on the test results of these image corrections, types of appropriate image correction and correction parameters are determined so as to be made close to the read image from main scanning.

(5) In correlation with “the reading condition during main scanning”, the determined image correction type(s) and correction parameter(s) are stored as table data. Furthermore, if the “reading condition during prescanning” is variable, determined image correction types and correction parameters are stored as table data in correlation with the different possible combinations of “the reading condition during main scanning” and “the reading condition during prescanning”.

The computer 15 refers to this table data based on “the reading condition during main scanning” (or “the reading condition of both scannings”) determined at step S2, and determines the image correction type(s) and correction parameter(s).

In step S13, the computer 15 performs the image correction(s) (e.g., white balance adjustment, line emphasis, noise removal, chroma correction, gradation conversion, etc.) determined at step S12 with respect to the alternative image.

In step S14, the computer 15 outputs the alternative image instead of a main scanned image. This alternative image is used, as an output result of the scanner 1, for input to an image processing program, an image display, image printing, or the like. The document reading operation is completed by this operation.

As explained above, in this embodiment, if the reading resolution during main scanning is less than the reading resolution during prescanning, an alternative image is generated from the read image from prescanning. In this case, the reading operation of main scanning is omitted, and the time required for document reading can be shortened.

In particular, in the case of an image to be used on the World Wide Web or an image attached to electronic mail, there are many cases in which the reading resolution during main scanning is lower than, for example, 100 dpi. Therefore, in this type of image reading, the image reading can be completed in a short period of time by omitting a main scanning operation.

Furthermore, in this embodiment, if the difference of the reading condition of both scans is outside of the predetermined allowable range, main scanning is performed regardless of the reading resolution. Due to this type of operation, an image with good quality in which the reading conditions are within an allowable range can be reliably obtained.

Additionally, in this embodiment, when main scanning is omitted, in order to reduce differences between “the reading condition which was selected for use during main scanning” and “the reading condition used during prescanning”, image correction is performed for the alternative image. Therefore, a more appropriate alternative image can be obtained.

According to the above-described embodiment, image correction is performed after resolution is converted. However, this invention is not limited to this example. In the case of an image correction which can be more effectively performed in a state with many pixels, it is preferable that the image correction be performed before resolution conversion, when there are more pixels.

Additionally, in the above-described embodiment, “preview image creation processing” and “determination of the document reading condition” are performed by one prescanning. Because of this, in a state where main scanning is omitted, image reading can be completed with only one prescanning. As a result, the time required for image reading can be greatly reduced.

Furthermore, in the above-mentioned embodiment, “preview image creation processing” and “determination of the document reading condition” are performed. However, this invention is not limited to this example. Prescanning also can be performed with a purpose of either one of “preview image creation processing” and “determination of the document reading condition.”

For example, if the reading condition during main scanning is manually set in advance, the determination processing of the reading condition by prescanning can be omitted. Furthermore, in this case, by performing prescanning under the same reading condition as in main scanning, it is possible to make a more suitable alternative image.

Furthermore, for example, when the reading range during the main scanning is already determined, and if preview display is not needed, generation of the preview image by prescanning can be omitted. Furthermore, in this case, by performing prescanning within the same reading range as in the main scanning, the cutting processing of the above-mentioned step S9 can be omitted.

Furthermore, this invention can be used with systems that perform prescanning two or more times. For example, “optimization of the reading condition of the document” may be performed by one time scanning, and “generation of the preview image at the optimal reading condition” may be performed by the following prescanning. In this case as well, by applying aspects of this invention, the main scanning can be omitted under appropriate circumstances. Furthermore, in this case, it is preferable that an alternative image is generated from the second prescanning which is performed under the optimal reading condition(s).

Furthermore, in this embodiment, a case is explained in which this invention is implemented by the driver program of the computer 15. However, this invention is not limited to this example. The functionality of this invention also can be incorporated into a general image processing program or the like.

Furthermore, for example, in the internal portion (e.g., CPU 25) of the scanner 1, by comparing the reading resolution during prescanning/main scanning, it also can be determined whether the main scanning can be omitted. For example, in the internal portion (e.g., CPU 25) of the scanner 1, the resolution of the read image of the prescanning can be converted, and an alternative image can be generated.

Additionally, in this embodiment, a case is explained in which the main scanning image is created from prescanning data. However, the main scanning image also can be created from a preview image.

Thus, according to some aspects of this invention, when the reading resolution during the main scanning is less than or equal to the reading resolution of prescanning, by converting the resolution of the read image from prescanning (if necessary), an alternative image is generated instead of performing the main scanning. Because of this, the main scanning can be omitted, and the reading operation of the image can be simplified.

In the illustrated example, the document reading device transmits light through a transparent document, and uses a driven light source and drives the document as well. The invention is not limited to the illustrated embodiment. For example, the invention can be used with document readers that read light that is reflected from documents rather than transmitted through the documents. In addition, the invention can be used with document readers that use a stationary line sensor instead of one that is driven. The line sensor can, for example, be a one-dimensional line sensor array or a two dimensional line sensor array. In addition, the invention can be used with document readers that maintain the document stationary instead of driving the document. Various combinations are possible.

The invention further includes, as another aspect, the control program described above that can be executed by the controller (e.g., computer 15) to control the image reading device as described above. The control program can be provided as a computer-readable computer program product, such as, e.g., a computer-readable recording medium on which the control program is recorded, or it may be a transmittable carrier wave in which the control program is embodied as a data signal. The control program can be implemented in an application specific integrated circuit (ASIC). The control program can be transmitted by a carrier wave over a communications network such as, for example, the World Wide Web and/or transmitted in a wireless fashion, for example, by radio waves or by infrared waves. The control program also can be transmitted from a remote storage facility to a local control unit. In such an arrangement, the local control unit interacts with the remote storage facility to transfer all or part of the program, as needed, for execution by the local unit. Accordingly, the local unit does not require a large amount of memory capacity. The computer-readable recording medium can be, e.g., a CD-ROM, a computer hard drive, RAM, or other types of memories that are readily removable or intended to remain fixed within the computer.

In the illustrated embodiment, the controller (computer 15) preferably is implemented using a suitably programmed general purpose computer, e.g., a microprocessor, microcontroller or other processor device (CPU or MPU). It will be appreciated by those skilled in the art, that the controller also can be implemented as a single special purpose integrated circuit (e.g., ASIC) having a main or central processor section for overall, system-level control, and separate sections dedicated to performing various different specific computations, functions and other processes under control of the central processor section. The controller also can be implemented using a plurality of separate dedicated or programmable integrated or other electronic circuits or devices (e.g., hardwired electronic or logic circuits such as discrete element circuits, or programmable logic devices such as PLDs, PLAs, PALs or the like). The controller also can be implemented using a suitably programmed general purpose computer in conjunction with one or more peripheral (e.g., integrated circuit) data and signal processing devices. In general, any device or assembly of devices on which a finite state machine capable of implementing the described procedures can be used as the calculation devices/controller of the invention.

While the invention has been described with reference to preferred embodiments thereof, it is to be understood that the invention is not limited to the preferred embodiments or constructions. To the contrary, the invention is intended to cover various modifications and equivalent arrangements. In addition, while the various elements of the preferred embodiments are shown in various combinations and configurations, that are exemplary, other combinations and configurations, including more, less or only a single element, are also within the spirit and scope of the invention.

What is claimed is:

1. An image reading device, comprising:
document reading means for reading an image of a document;
prescanning means for performing prescanning of the document by operating the document reading means, and performing at least one of: (i) generating a preview image of the document, and (ii) determining a reading condition of the document;
operation input means for receiving a user input for a reading resolution to be used during main scanning;
main scanning means for outputting a main scanning image by operating the document reading means to perform main scanning of the document, when the reading resolution to be used during the main scanning is higher than a reading resolution used for the prescanning; and
main scanning alternative means for, as an alternative to performing the main scanning, generating and outputting an alternative image based on the read image obtained from the prescanning, when the reading resolution to be used during the main scanning is less than or equal to the reading resolution used for the prescanning.

2. The image reading device of claim 1, wherein the main scanning alternative means generates and outputs the alternative image by: (1) converting a resolution of the read image obtained from the prescanning, (2) generating the alternative image adjusted to the resolution to be used during the main scanning, and (3) outputting the alternative image instead of the main scanning image.

3. The image reading device of claim 1, wherein the main scanning means determines whether a difference between (a) a reading condition used for the prescanning and (b) a reading condition which is scheduled to be used during the main scanning, is outside of a predetermined allowable range, and if the difference is outside of the predetermined allowable range, regardless of the reading resolution, the main scanning is performed, and the main scanning image is output.

4. The image reading device of claim 1, wherein the main scanning alternative means selects an image correction according to a difference between (a) a reading condition used during the prescanning, and (b) a reading condition which is scheduled to be used during the main scanning, and generates the alternative image to which the image correction has been performed.

5. The image reading device of claim 3, wherein the main scanning alternative means selects an image correction according to the difference between (a) the reading condition used during the prescanning, and (b) the reading condition which is scheduled to be used during the main scanning, and generates the alternative image to which the image correction has been performed.

6. An image reading device, comprising:
a document reader that reads an image of a document; and
a controller that:
performs prescanning of the document using the document reader, and that performs at least one of: (i) generating a preview image of the document, and (ii) determining a reading condition of the document;
receives a user input for a reading resolution to be used during main scanning;
when the received reading resolution to be used during the main scanning is higher than a reading resolution used for the prescanning, performs the main scanning of the document using the document reader, and outputs a main scanning image of the document; and
when the reading resolution to be used during the main scanning is less than or equal to the reading resolution used for the prescanning, performs, as an alternative to the main scanning, generation and output of an alternative image based on the read image obtained from the prescanning.

7. The image reading device of claim 6, wherein the controller generates and outputs the alternative image by: (1) conversion of a resolution of the read image obtained from the prescanning, (2) generation of the alternative image adjusted to the resolution to be used during the main scanning, and (3) output of the alternative image instead of the main scanning image.

8. The image reading device of claim 6, wherein the controller also determines whether a difference between (a) a reading condition used for the prescanning and (b) a reading condition which is scheduled to be used during the main scanning, is outside of a predetermined allowable range, and if the difference is outside of the predetermined allowable range, regardless of the reading resolution, the main scanning is performed, and the main scanning image is output.

9. The image reading device of claim 6, wherein the controller also selects an image correction according to a difference between (a) a reading condition used during the prescanning, and (b) a reading condition which is scheduled to be used during the main scanning, and generates the alternative image to which the image correction has been performed.

10. The image reading device of claim 8, wherein the controller also selects an image correction according to the difference between (a) the reading condition used during the prescanning, and (b) the reading condition which is scheduled to be used during the main scanning, and generates the alternative image to which the image correction has been performed.

11. An image reading method that controls a document reader to read an image of a document, the method comprising steps of:
performing prescanning of the document using the document reader, and performing at least one of: (i) generating a preview image of the document, and (ii) determining a reading condition of the document;
receiving a user input for a reading resolution to be used during main scanning;
when the received reading resolution to be used during the main scanning is higher than a reading resolution used for the prescanning, performing the main scanning of the document by controlling the document reader, and outputting the main scanning image; and
when the received reading resolution to be used during the main scanning is less than or equal to the reading resolution used for the prescanning, generating and outputting an alternative image instead of the main scanning image, the alternative image is based on the read image obtained from the prescanning.

12. The method of claim 11, wherein the step of generating and outputting the alternative image includes: (1) converting a resolution of the read image obtained from the prescanning, (2) generating the alternative image adjusted to the resolution to be used during the main scanning, and (3) outputting the alternative image instead of the main scanning image.

13. The method of claim 11, further comprising determining whether a difference between (a) a reading condition used for the prescanning and (b) a reading condition which is scheduled to be used during the main scanning, is outside of a predetermined allowable range, and if the difference is outside of the predetermined allowable range, regardless of the reading resolution, performing the main scanning and outputting the main scanning image.

14. The method of claim 11, further comprising selecting an image correction according to a difference between (a) a reading condition used during the prescanning, and (b) a reading condition which is scheduled to be used during the main scanning, and generating the alternative image to which the image correction has been performed.

15. The method of claim 13, further comprising selecting an image correction according to the difference between (a) the reading condition used during the prescanning, and (b) the reading condition which is scheduled to be used during the main scanning, and generating the alternative image to which the image correction has been performed.

16. A computer-readable, computer program product having computer-executable instructions for performing the method recited in claim 11.

17. A computer-readable, computer program product having computer-executable instructions for performing the method recited in claim 12.

18. A computer-readable, computer program product having computer-executable instructions for performing the method recited in claim 13.

19. A computer-readable, computer program product having computer-executable instructions for performing the method recited in claim 14.

20. A computer-readable, computer program product having computer-executable instructions for performing the method recited in claim 15.

21. An image reading device, comprising:
a document reader that reads an image of a document; and
a controller that:
performs prescanning of the document using the document reader;
determines at least one reading condition to be used for main scanning of the document;
determines whether a difference between (a) at least one reading condition used for the prescanning and (b) the at least one reading condition determined to be used for the main scanning, is outside of a predetermined allowable range;
when the determined difference is outside of the predetermined allowable range, performs the main scanning of the document using the document reader, and outputs a main scanning image of the document; and
when the determined difference is not outside of the predetermined allowable range, performs, as an alternative to the main scanning, generation and output of an alternative image based on the read image obtained from the prescanning.

22. The image reading device of claim 21, wherein the controller generates and outputs the alternative image by: (1) conversion of a resolution of the read image obtained from the prescanning, (2) generation of the alternative image adjusted to a resolution to be used during the main scanning, and (3) output of the alternative image instead of the main scanning image.

23. The image reading device of claim 21, wherein the controller also selects an image correction according to the difference between (a) the at least one reading condition used during the prescanning, and (b) the at least one reading condition determined to be used for the main scanning, and generates the alternative image to which the image correction has been performed.

24. An image reading method that controls a document reader to read an image of a document, the method comprising steps of:
performing prescanning of the document using the document reader;
determining at least one reading condition to be used for main scanning of the document;
determining whether a difference between (a) at least one reading condition used for the prescanning and (b) the at least one reading condition determined to be used for the main scanning, is outside of a predetermined allowable range;
when the determined difference is outside of the predetermined allowable range, performing the main scanning of the document using the document reader, and outputting a main scanning image of the document; and
when the determined difference is not outside of the predetermined allowable range, performing, as an alternative to the main scanning, generation and output of an alternative image based on the read image obtained from the prescanning.

25. The method of claim 24, wherein the step of generating and outputting the alternative image includes: (1) converting a resolution of the read image obtained from the prescanning, (2) generating the alternative image adjusted to a resolution to be used during the main scanning, and (3) outputting the alternative image instead of the main scanning image.

26. The method of claim 24, further comprising the step of selecting an image correction according to the difference between (a) the at least one reading condition used during the prescanning, and (b) the at least one reading condition determined to be used for the main scanning, and generating the alternative image to which the image correction has been performed.

27. A computer-readable, computer program product having computer-executable instructions for performing the method recited in claim 24.

28. A computer-readable, computer program product having computer-executable instructions for performing the method recited in claim 25.

29. A computer-readable, computer program product having computer-executable instructions for performing the method recited in claim 26.
